(19) United States
(12) Patent Application Publication
(10) Pub. No.: US 2015/0153378 A1
(43) Pub. Date: Jun. 4, 2015

(54) MICRO ELECTRO MECHANICAL SYSTEMS SENSOR MODULE PACKAGE AND METHOD OF MANUFACTURING THE SAME

(71) Applicant: SAMSUNG ELECTRO-MECHANICS CO., LTD., Suwon-Si (KR)

(72) Inventors: Tae Hyun KIM, Suwon-Si (KR); Heung Woo Park, Suwon-Si (KR); Eun Jung Jo, Suwon-Si (KR)

(73) Assignee: SAMSUNG ELECTRO-MECHANICS CO., LTD., Suwon-Si (KR)

(21) Appl. No.: 14/550,851

(22) Filed: Nov. 21, 2014

(30) Foreign Application Priority Data
Dec. 2, 2013 (KR) 10-2013-0148480

(51) Int. Cl. G01P 15/105

(52) U.S. Cl. CPC G01P 15/105; B81B 3/0018

(57) ABSTRACT

Disclosed herein is a micro electro mechanical systems (MEMS) sensor module package. The MEMS sensor module package includes: an MEMS sensor; a base part formed so as to encapsulate the MEMS sensor with a resin; an external terminal provided on one surface of the base part; a through mold via (TMV) provided in the base part to electrically connect the external terminal and the MEMS sensor to each other; and an application specific integrated circuit (ASIC) stacked on the MEMS sensor. Compared to a MEMS sensor module package structure according to the prior art, the present invention is to reduce the entire size and implement electric shielding.

### CROSS REFERENCE TO RELATED APPLICATION

This application claims the benefit of Korean Patent Application No. 10-2013-0148480, filed on Dec. 2, 2013 entitled “Micro Electro Mechanical Systems (MEMS) Sensor Module Package and Method of Manufacturing the Same”, which is hereby incorporated by reference in its entirety into this application.

### BACKGROUND OF THE INVENTION

1. Technical Field

The present invention relates to a micro electro mechanical systems (MEMS) sensor module package and a method of manufacturing the same.

2. Description of the Related Art

A micro electro mechanical systems (MEMS), which is a technology of manufacturing a micrometer (μm) or millimeter (mm) sized micro precision machine based on a semiconductor process technology called a micro electro mechanical system, a micro electro control technology, or the like, may manufacture a micro mechanical structure such as a very large scale integrated circuit, a micro gear having a thickness corresponding to a half of a hair, a nail-sized hard disk, a nail-sized sensor, a nail-sized actuator, or the like, by processing silicon, crystal, glass, or the like, and has a precise three-dimensional structure in which a surface is micro-machined by a depositing method, an etching method such as a bulk silicon etching method, or the like.

An MEMS sensor manufactured using the MEMS has been used in various applications, for example, a military application such as an artificial satellite, a missile, an unmanned aircraft, or the like, a vehicle application such as an air bag, electronic stability control (ESC), a black box for a vehicle, or the like, a hand shaking prevention application of a camcorder, a motion sensing application of a mobile phone or a game machine, or the like.

Meanwhile, the MEMS sensor generally has a configuration in which a mass body is adhered to an elastic substrate such as a membrane, or the like, in order to measure an acceleration, an angular velocity, a force, a pressure, or the like. That is, through the above-mentioned configuration, the MEMS sensor may calculate the acceleration by measuring an inertial force applied to the mass body, calculate the angular velocity by measuring a Coriolis force applied to the mass body, and calculate the force by measuring an external force directly applied to the mass body.

Next, a method of measuring the acceleration and the angular velocity using the MEMS sensor will be described below in detail.

First, the acceleration may be calculated by Newton's law of motion “F=ma”, where “F” represents an inertial force applied to the mass body, “m” represents a mass of the mass body, and “a” is an acceleration to be measured. Among others, the acceleration a may be obtained by sensing the inertial force F applied to the mass body and dividing the sensed inertial force F by the mass m of the mass body that is a predetermined value.

Further, the angular velocity may be calculated by a Coriolis force “F=2mΩ×v”, where “F” represents the Coriolis force applied to the mass body, “m” represents the mass of the mass body, “Ω” represents the angular velocity to be measured, and “v” represents the motion velocity of the mass body. Among others, since the motion velocity V of the mass body and the mass m of the mass body are values known in advance, the angular velocity Ω may be obtained by detecting the Coriolis force (F) applied to the mass body.

Meanwhile, the MEMS sensor is packaged in a structure in which after an application specific integrated circuit (ASIC) is bonded onto sensor devices using an epoxy, or the like, each of the sensor devices is electrically connected to a printed circuit board (PCB) by wire bonding.

The MEMS sensor will be described in more detail with reference to Patent Document 1. An MEMS sensor module package structure according to the prior art is configured to include a substrate having conductive patterns and lands, a semiconductor die provided on a printed circuit board (PCB) and electrically connected to the conductive patterns, an encapsulant formed on the substrate so as to encapsulate the semiconductor die, and a through mold via (TMV) having one end electrically connected to the conductive patterns while penetrating through the encapsulant and the other end exposed to the outside.

Here, the semiconductor die is electrically connected to a semiconductor pattern of the substrate through a conductive wire. In addition, the encapsulant is formed by molding any one selected among a general epoxy resin, a silicon resin, and an equivalent thereof to maintain an appearance of a semiconductor device.

However, in the MEMS sensor module package structure according to the prior art, as described above the printed circuit board (PCB) is used, which causes an increase in a size. In addition, since the semiconductor die is electrically connected to the printed circuit board (PCB) through the conductive wire, a space for bonding the conductive wire is required, which also causes an increase in a size.

Meanwhile, in the MEMS sensor module package structure according to the prior art, electrical characteristics may be deteriorated. The reason is that long wire bonding is performed for electrical shielding, which may generate a wire sweep problem to cause yield deterioration.

### PRIOR ART DOCUMENT

### Patent Document

(Patent Document 1) KR2010-0008061 A

### SUMMARY OF THE INVENTION

Therefore, the present invention is to significantly reduce the entire size and implement electrical shielding by solving problems of a micro electro mechanical systems (MEMS) sensor module package structure according to the prior art including the above-mentioned Patent Document 1.

The present invention has been made in an effort to provide an MEMS sensor module package capable of easily reducing a size and easily implementing electrical shielding.

Further, the present invention has been made in an effort to provide a method of manufacturing an MEMS sensor module package capable of simplifying a process and improving a yield by applying a frame mold via and an application specific integrated circuit (ASIC) wafer level process.

According to a preferred embodiment of the present invention, there is provided an MEMS sensor module package including: an MEMS sensor; a base part formed so as to encapsulate the MEMS sensor with a resin; an external terminal provided on one surface of the base part; a through mold via (TMV) provided in the base part to electrically connect the external terminal and the MEMS sensor to each other; and an ASIC stacked on the MEMS sensor.

The MEMS sensor may be a six-axis inertial sensor.

The MEMS sensor module package may further include an electrical shielding layer interposed between the MEMS sensor and the base part.

The MEMS sensor module package may further include a three-axis geomagnetic sensor provided under the base part and electrically connected to the MEMS sensor.

The base part may close one side of the MEMS sensor and open the other side of the MEMS sensor to the outside.

The base part may close both sides of the MEMS sensor.

The external terminal may include a solder bump.

According to another preferred embodiment of the present invention, there is provided a method of manufacturing an MEMS sensor module package, including: (a) bonding an MEMS sensor to an ASIC; (b) encapsulating the MEMS sensor with a resin to form a base part; (c) bonding a frame mold via (FMV) in which a frame and a TMV are formed integrally with each other to the base part to electrically connect the FMV to the MEMS sensor; (d) removing or patterning the frame; and (e) forming an external terminal on the TMV.

The step (b) may be performed by applying a liquid or powder resin.

The method may further include, before the step (b), interposing an electrical shielding layer between the MEMS sensor and the base part.

The method may further include (f) bonding a three-axis geomagnetic sensor to the base part to electrically connect the three-axis geomagnetic sensor to the MEMS sensor.

The step (a) may be performed by bonding the MEMS sensor to an ASIC wafer.

The method may further include (g) sawing the ASIC wafer.

According to still another preferred embodiment of the present invention, there is provided a method of manufacturing an MEMS sensor module package, including: (a) bonding an MEMS sensor to an ASIC; (b) bonding an FMV in which a frame and a TMV are formed integrally with each other to the MEMS sensor to electrically connect the FMV to the MEMS sensor; (c) pushing a resin between the MEMS sensor and the FMV to form a base part; (d) removing or patterning the frame; and (e) forming an external terminal on the TMV.

The step (b) may be performed by applying a liquid or powder resin.

The method may further include, before the step (b), forming an electrical shielding layer under the MEMS sensor.

The method may further include (f) bonding a three-axis geomagnetic sensor to the base part to electrically connect the three-axis geomagnetic sensor to the MEMS sensor.

The step (a) may be performed by bonding the MEMS sensor to an ASIC wafer.

The method may further include (g) sawing the ASIC wafer.

### BRIEF DESCRIPTION OF THE DRAWINGS

The above and other objects, features and advantages of the present invention will be more clearly understood from the following detailed description taken in conjunction with the accompanying drawings, in which:

FIG. 1 is a cross-sectional view showing a micro electro mechanical systems (MEMS) sensor module package according to a first preferred embodiment of the present invention;

FIG. 2 is a cross-sectional view showing an MEMS sensor module package according to a second preferred embodiment of the present invention;

FIG. 3 is a cross-sectional view showing an MEMS sensor module package according to a third preferred embodiment of the present invention;

FIG. 4 is a cross-sectional view showing an MEMS sensor module package according to a fourth preferred embodiment of the present invention; and

FIGS. 5 to 9 are cross-sectional views showing a method of manufacturing an MEMS sensor module package according to a preferred embodiment of the present invention.

### DESCRIPTION OF THE PREFERRED EMBODIMENTS

The objects, features and advantages of the present invention will be more clearly understood from the following detailed description of the preferred embodiments taken in conjunction with the accompanying drawings. Throughout the accompanying drawings, the same reference numerals are used to designate the same or similar components, and redundant descriptions thereof are omitted. Further, in the following description, the terms “first”, “second”, “one side”, “the other side” and the like are used to differentiate a certain component from other components, but the configuration of such components should not be construed to be limited by the terms. Further, in the description of the present invention, when it is determined that the detailed description of the related art would obscure the gist of the present invention, the description thereof will be omitted.

Hereinafter, preferred embodiments of the present invention will be described in detail with reference to the attached drawings.

In a micro electro mechanical systems (MEMS) sensor module package according to a preferred embodiment of the present invention, a substrate of a printed circuit board (PCB) is removed, and an MEMS sensor and an application specific integrated circuit (ASCI) are configured in a stack structure, such that a module may be implemented within a size of the ASIC. Therefore, size reduction required in a mobile apparatus such as a smart phone may be easily implemented.

That is, the MEMS sensor module package is configured by applying and molding a liquid or powder resin instead of the PCB usually used in order to mount the MEMS sensor and stacking the MEMS sensor and the ASIC in a stack structure and bonding them to each other. Therefore, the above-mentioned size reduction is easy and the ASIC is disposed at an outside of a sensor module to serve as an electrical shielding function, such that electrical shielding is possible without an increase in a thickness.

Here, the MEMS sensor includes an inertial sensor, which will be schematically described below. The inertial sensor, which is a component detecting an inertial force of movement to provide various navigation related information such as an acceleration, a velocity, a direction, a distance, and the like, of a moving object, which is a target to be measure and using a principle of detecting an inertial force acting on an inertial body by an applied acceleration, is divided into an accelerometer and a gyroscope. An inertial sensor in a scheme of using laser and an inertial sensor in a non-mechanical scheme have been developed. The inertial sensor has been used in fields such as a motion sensor of an air bag of a vehicle, a camcoder, a cellular phone, general home appliances, or the like, a navigation field, a control field, and the like, of an airplane and a vehicle.

Meanwhile, the MEMS sensor module package according to the preferred embodiment of the present invention may be configured by stacking the MEMS sensor, the ASIC, and a geomagnetic sensor in a stack structure and bonding them to each other. As an example, a six-axis inertial sensor is adopted as the MEMS sensor and a three-axis geometric sensor is adopted as the geomagnetic sensor, such that a nine-axis sensor module may be implemented.

An example of the geomagnetic sensor, which is a sensor used to detect geomagnetism, includes a fluxgate magnetometer using a magnetic saturation phenomenon of a ferromagnetic substance of a rotating coil, a proton magnetometer using nuclear magnetic resonance of a proton, an optical pumping magnetometer using Zeeman effect of rubidium or cesium atoms, and the like. Therefore, any one among these magnetometers is selected and is stacked on and bonded to a resin encapsulating the MEMS sensor in a stack structure to thereby be electrically connected to the resin, thereby making it possible to easily implement the MEMS sensor module package.

Since the MEMS sensor module package may be manufactured by a method of encapsulating the MEMS sensor with the liquid or powder resin by a wafer level process using an ASIC wafer, the PCB may be removed, and a manufacturing process may be easily simplified, such that a yield may be improved.

Further, a technology of a frame mold via (FMV) in which a frame and a via are formed integrally with each other is applied to perform a manufacturing process, thereby making it possible to easily prevent deformation of the via due to a pressure. As a result, reliability may be easily improved.

Here, the frame mold via (FMV) may be formed by various materials and methods. For example, a metal material such as copper (Cu) or various alloys thereof such as bronze and brass, nickel (Ni) or an alloy thereof or the like, may be used or a conductive or non-conductive epoxy, or the like, may be used as a material of the FMV.

Further, in the case in which the epoxy is used as the material of the FMV, the via may be injection-molded using an injection mold in addition to stencil printing or be formed by punching. Further, in the case in which the non-conductive resin is used as the material of the FMV, an electrical connecting structure may be formed using a conductive resin or electroless plating.

Hereinafter, preferred embodiments of the present invention will be described in detail with reference to the accompanying drawings.

### First Preferred Embodiment

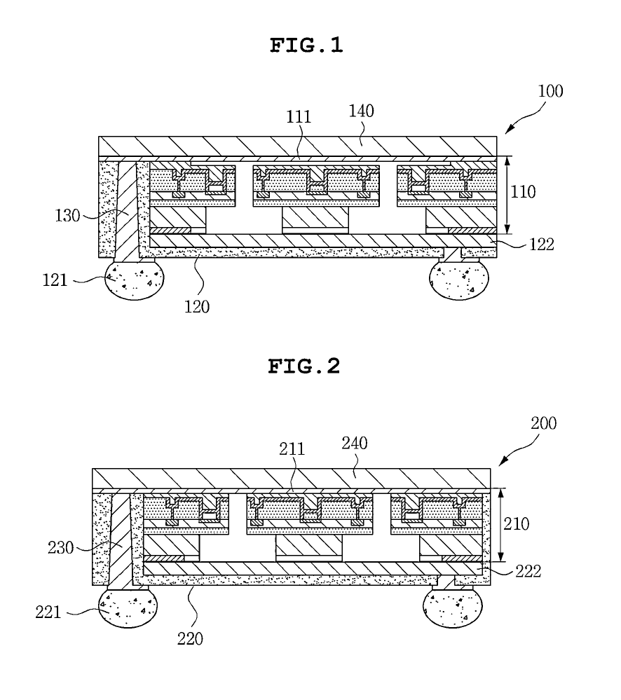

As shown in FIG. 1, an MEMS sensor module package 100 according to a first preferred embodiment of the present invention includes a six-axis inertial sensor adopted as an MEMS sensor 110 and a base part 120 formed so as to encapsulate one side and a bottom of the six-axis inertial sensor by applying a liquid or powder resin. Therefore, the other side of the MEMS sensor 110, that is, the right side in FIG. 1 is opened to the outside.

The base part 120, which is a component corresponding to a base of the MEMS sensor module package 100, supports a stack structure of the MEMS sensor 110 and an ASIC 140 and enables external terminals 121 electrically connected to the MEMS sensor 110 and the ASIC 140 to be formed. Here, a shielding layer 122 performing an electrical shielding function together with the ASIC 140 may be interposed between the bottom of the MEMS sensor 110 and the base part 120. The shielding layer 122 is configured by attaching aluminum, or the like, capable of performing the electrical shielding function to the bottom of the MEMS sensor 110 and encapsulating the aluminum with a resin.

A solder bump is formed as the external terminal 121 under the base part 120 to electrically connect the MEMS sensor module package 100 to an external apparatus or another package. In addition, the base part 120 is provided with a through mold via (TMV) made of a conductive material including a conductive metal such as copper, palladium, titanium, gold, titanium nitride, nickel, or the like, and a resin to electrically connect the MEMS sensor 110 and the external terminal 121 to each other.

For example, the TMV 130 is disposed in the base part 120 by being inserted into the base part 120 using heat and pressure in a vacuum chamber and at the same time, performing temporal hardening on the resin. Therefore, an upper end of the TMV 130 contacts a circuit layer 111 formed on the MEMS sensor 110 while penetrating through the base part 120, and a lower end thereof contacts the external terminal 121, such that the external terminal 121 and the MEMS sensor 110 are electrically connected to each other.

Meanwhile, the ASIC 140 is stacked on the MEMS sensor 110 and contacts the circuit layer 111 to thereby be electrically connected to the MEMS sensor 110. That is, the MEMS sensor 110 and the ASIC 140 are configured in the stack structure, such that an upper surface of the ASIC 140 is disposed at a top of the MEMS sensor module package 100 to perform an electrical shielding function.

Therefore, since the MEMS sensor module package 100 according to the first preferred embodiment of the present invention is implemented within a size that is substantially the same as that of the ASIC 140, a size of the MEMS sensor module package 100 may be reduced as compared with the prior art by 1.5 mm or more, and the electrical shielding for upper and lower portions based on the base part 120 is possible.

### Second Preferred Embodiment

As shown in FIG. 2, an MEMS sensor module package 200 according to a second preferred embodiment of the present invention includes a six-axis inertial sensor adopted as an MEMS sensor 210 and a base part 220 formed so as to encapsulate both sides and a bottom of the six-axis inertial sensor by applying a liquid or powder resin. That is, both sides of the MEMS sensor 210 are closed by the base part 220.

The base part 220, which is a component corresponding to a base of the MEMS sensor module package 200, supports a stack structure of the MEMS sensor 210 and an ASIC 240 and enables external terminals 221 electrically connected to the MEMS sensor 210 and the ASIC 240 to be formed. Here, a shielding layer 222 performing an electrical shielding function together with the ASIC 240 may be interposed between the bottom of the MEMS sensor 210 and the base part 220. The shielding layer 222 is configured by attaching aluminum, or the like, capable of performing the electrical shielding function to the bottom of the MEMS sensor 210 and encapsulating the aluminum with a resin.

A solder bump is formed as the external terminal 221 under the base part 220 to electrically connect the MEMS sensor module package 200 to an external apparatus or another package. In addition, the base part 220 is provided with a TMV made of a conductive material including a conductive metal such as copper, palladium, titanium, gold, titanium nitride, nickel, or the like, and a resin to electrically connect the MEMS sensor 210 and the external terminal 221 to each other.

For example, the TMV 230 is disposed in the base part 220 by being inserted into the base part 220 using heat and pressure in a vacuum chamber and at the same time, performing temporal hardening on the resin. Therefore, an upper end of the TMV 230 contacts a circuit layer 211 formed on the MEMS sensor 210 while penetrating through the base part 220, and a lower end thereof contacts the external terminal 221, such that the external terminal 221 and the MEMS sensor 210 are electrically connected to each other.

Meanwhile, the ASIC 240 is stacked on the MEMS sensor 210 and contacts the circuit layer 211 to thereby be electrically connected to the MEMS sensor 210. That is, the MEMS sensor 210 and the ASIC 240 are configured in the stack structure, such that an upper surface of the ASIC 240 is disposed at a top of the MEMS sensor module package 200 to perform an electrical shielding function.

Therefore, since the MEMS sensor module package 200 according to the second preferred embodiment of the present invention is implemented within a size that is substantially the same as that of the ASIC 240, a size of the MEMS sensor module package 200 may be reduced as compared with the prior art by 1.5 mm or more, and the electrical shielding for upper and lower portions based on the base part 220 is possible.

### Third Preferred Embodiment

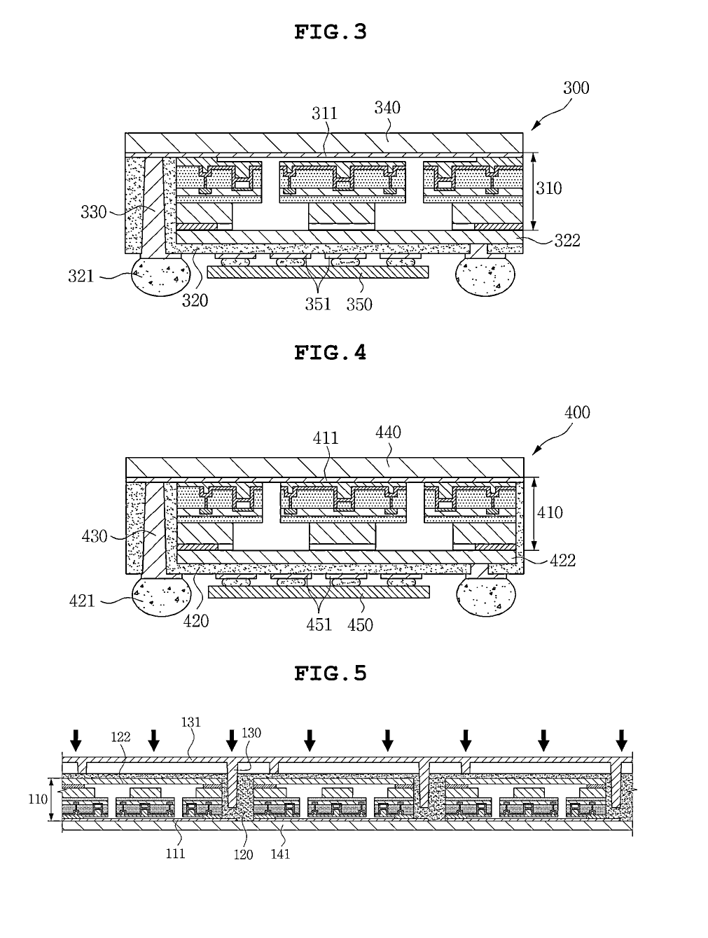

As shown in FIG. 3, an MEMS sensor module package 300 according to a third preferred embodiment of the present invention includes a six-axis inertial sensor adopted as an MEMS sensor 310 and a base part 320 formed so as to encapsulate one side and a bottom of the six-axis inertial sensor by applying a liquid or powder resin. Therefore, the other side of the MEMS sensor 310, that is, the right side in FIG. 1 is opened to the outside.

The base part 320, which is a component corresponding to a base of the MEMS sensor module package 300, supports a stack structure of the MEMS sensor 310 and an ASIC 340 and enables external terminals 321 electrically connected to the MEMS sensor 310 and the ASIC 340 to be formed. Here, a shielding layer 322 performing an electrical shielding function together with the ASIC 340 may be interposed between the bottom of the MEMS sensor 310 and the base part 320. The shielding layer 322 is configured by attaching aluminum, or the like, capable of performing the electrical shielding function to the bottom of the MEMS sensor 310 and encapsulating the aluminum with a resin.

A solder bump is formed as the external terminal 321 under the base part 320 to electrically connect the MEMS sensor module package 300 to an external apparatus or another package. In addition, the base part 320 is provided with a TMV made of a conductive material including a conductive metal such as copper, palladium, titanium, gold, titanium nitride, nickel, or the like, and a resin to electrically connect the MEMS sensor 310 and the external terminal 321 to each other.

For example, the TMV 330 is disposed in the base part 320 by being inserted into the base part 320 using heat and pressure in a vacuum chamber and at the same time, performing temporal hardening on the resin. Therefore, an upper end of the TMV 330 contacts a circuit layer 311 formed on the MEMS sensor 310 while penetrating through the base part 320, and a lower end thereof contacts the external terminal 321, such that the external terminal 321 and the MEMS sensor 310 are electrically connected to each other.

Meanwhile, the ASIC 340 is stacked on the MEMS sensor 310 and contacts the circuit layer 311 to thereby be electrically connected to the MEMS sensor 310. That is, the MEMS sensor 310 and the ASIC 340 are configured in the stack structure, such that an upper surface of the ASIC 340 is disposed at a top of the MEMS sensor module package 300 to perform an electrical shielding function.

In addition, a three-axis geomagnetic sensor is stacked as a geomagnetic sensor 350 on a side opposite to the ASIC 340, that is, under the base part 320, to form a stack structure. In this case, circuit patterns 351 are formed under the base part 320 to electrically connect the geomagnetic sensor 350 to the base part 320.

In the MEMS sensor module package 300 according to the third preferred embodiment of the present invention, the electrical shielding for upper and lower portions based on the base part 320 is possible. Further, the MEMS sensor 310, the ASIC 340, and the geomagnetic sensor 350 are configured in the stack structure, thereby making it possible to implement a nine-axis sensor module.

### Fourth Preferred Embodiment

As shown in FIG. 4, an MEMS sensor module package 400 according to a fourth preferred embodiment of the present invention includes a six-axis inertial sensor adopted as an MEMS sensor 410 and a base part 420 formed so as to encapsulate both sides and a bottom of the six-axis inertial sensor by applying a liquid or powder resin. That is, both sides of the MEMS sensor 410 are closed by the base part 420.

The base part 420, which is a component corresponding to a base of the MEMS sensor module package 400, supports a stack structure of the MEMS sensor 410 and an ASIC 440 and enables external terminals 421 electrically connected to the MEMS sensor 410 and the ASIC 440 to be formed. Here, a shielding layer 422 performing an electrical shielding function together with the ASIC 440 may be interposed between the bottom of the MEMS sensor 410 and the base part 420. The shielding layer 422 is configured by attaching aluminum, or the like, capable of performing the electrical shielding function to the bottom of the MEMS sensor 410 and encapsulating the aluminum with a resin.

A solder bump is formed as the external terminal 421 under the base part 420 to electrically connect the MEMS sensor module package 400 to an external apparatus or another package. In addition, the base part 420 is provided with a TMV made of a conductive material including a conductive metal such as copper, palladium, titanium, gold, titanium nitride, nickel, or the like, and a resin to electrically connect the MEMS sensor 410 and the external terminal 421 to each other.

For example, the TMV 430 is disposed in the base part 420 by being inserted into the base part 420 using heat and pressure in a vacuum chamber and at the same time, performing temporal hardening on the resin. Therefore, an upper end of the TMV 430 contacts a circuit layer 411 formed on the MEMS sensor 410 while penetrating through the base part 420, and a lower end thereof contacts the external terminal 421, such that the external terminal 421 and the MEMS sensor 410 are electrically connected to each other.

Meanwhile, the ASIC 440 is stacked on the MEMS sensor 410 and contacts the circuit layer 411 to thereby be electrically connected to the MEMS sensor 410. That is, the MEMS sensor 410 and the ASIC 440 are configured in the stack structure, such that an upper surface of the ASIC 440 is disposed at a top of the MEMS sensor module package 400 to perform an electrical shielding function.

In addition, a three-axis geomagnetic sensor is stacked as a geomagnetic sensor 450 on a side opposite to the ASIC 440, that is, under the base part 420, to form a stack structure. In this case, circuit patterns 451 are formed under the base part 420 to electrically connect the geomagnetic sensor 450 to the base part 420.

In the MEMS sensor module package 400 according to the fourth preferred embodiment of the present invention, the electrical shielding for upper and lower portions based on the base part 420 is possible. Further, the MEMS sensor 410, the ASIC 440, and the geomagnetic sensor 450 are configured in the stack structure, thereby making it possible to implement a nine-axis sensor module.

Meanwhile, all of the MEMS sensor module packages according to the first to fourth preferred embodiments of the present are manufactured by the following method, which will be described in detail with reference to the accompanying drawings. Hereinafter, a method of manufacturing an MEMS sensor module package will be described based on the first preferred embodiment of the present invention.

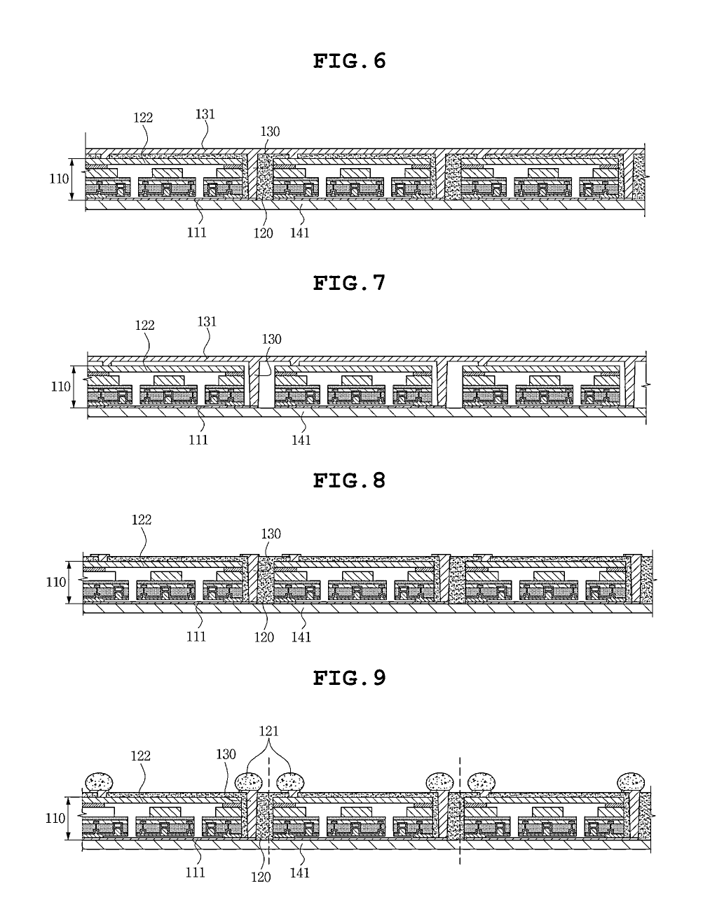

As shown in FIGS. 5 and 6, in the method of manufacturing an MEMS sensor module package 100 according to the preferred embodiment of the present invention, a six-axis inertial sensor is bonded as the MEMS sensor 110 to an upper portion of an ASIC wafer. Here, the MEMS sensor 100 is configured so that the circuit layer 111 is directed toward the ASIC wafer 141 and is then bonded to the ASIC wafer 141.

Then, a liquid or solid powder resin is applied to the ASIC wafer 141 to entirely encapsulate the MEMS sensor, thereby forming the base part 120 corresponding to a base of the MEMS sensor module package 100. Here, before the resin is applied to the ASIC wafer 141 to form the base part 120, the shielding layer 122 may be interposed between the MEMS sensor 110 and the base part 120 by attaching aluminum, or the like, capable of performing an electrical shielding function to an upper portion of the MEMS sensor 110.

After the base part 120 is formed, a process of performing encapsulation by inserting and bonding a frame mold via (FMV) in which a frame 131 and the TMV 130 are formed integrally with each other using a conductive material including a conductive metal such as copper, palladium, titanium, gold, titanium nitride, nickel, or the like, and a resin into the base part 120 using heat and pressure in a vacuum chamber and at the same time, performing temporal hardening of the resin is conducted.

Meanwhile, a method of bonding the FMV to the MEMS sensor 110 and then filling a liquid or solid powder resin between the MEMS sensor 110 the FMV to form the base part 120 is also possible.

As shown in FIG. 7, the FMV in which the frame 131 and the TMV 130 are formed integrally with each other is bonded to the circuit layer 111 of the MEMS sensor 110 to electrically connect the TMV 130 and the circuit layer 111 to each other. Then, the liquid or solid powder resin is pushed and filled in a space formed between the frame 131 and the MEMS sensor 110 to form the base part 120.

Here, before the FMV is bonded to the MEMS sensor 110, aluminum, or the like, capable of performing an electrical shielding function may be attached to the upper portion of the MEMS sensor 110 to form the shielding layer 122. Then, after the FMV is bonded to an upper portion of the shielding layer 122, the base part 120 may be formed.

As shown in FIGS. 8 and 9, after the bonding of the FMV to the MEMS sensor 100 is completed, the frame 131 configuring the FMV is removed or patterned. Here, the reason why the frame 131 is patterned instead of being removed is to electrically connect the MEMS sensor module package 100 and a three-axis geomagnetic sensor to each other at the time of building up a nine-axis sensor module by stacking the three-axis geomagnetic sensor on the MEMS sensor module package 100.

When the removal or the patterning of the frame 131 is completed, the external terminal 121 is formed at one end of the TMV exposed to the outside of the base part 120. The external terminal 121 may be configured of for example, a solder bump formed by applying a solder paste and allowing the solder paste to reflow.

The external terminal 121 is electrically connected to the MEMS sensor 110 through the TVM 130 to electrically connect the MEMS sensor module package 400 to an external apparatus or another package.

Therefore, in the method of manufacturing an MEMS sensor module package according to the preferred embodiment of the present invention, a wafer level process is applied, thereby making it possible to simultaneously package a plurality of MEMS sensors 110. Then, a singulation process is finally performed through sawing, thereby making it possible to provide individual MEMS sensor module packages.

According to the preferred embodiments of the present invention, a printed circuit board that has been used in the prior art may be removed and a wire bonding process and a process of plating or coating an outer portion that have been performed in the prior art are not required, such that a size of the MEMS sensor module package may be reduced so as to satisfy miniaturization of a mobile apparatus. In addition, the MEMS sensor module package may be implemented within a size of the ASIC, which performs a kind of shielding function, thereby making it possible to perform electrical shielding without increasing a size.

Meanwhile, in the method of manufacturing an MEMS sensor module package according to the preferred embodiment of the present invention, a process of manufacturing an MEMS sensor module package is improved to be simplified, thereby making it possible to improve a yield. In addition, a technology of the frame mold via is applied to easily prevent deformation of the via, thereby making it possible to improve reliability. Further, the wafer level process is applied, such that the printed circuit board may be easily removed. As a result, a cost may be reduced.

Furthermore, in the case of patterning the frame instead of removing the frame from the via, since a three-axis geomagnetic sensor may be easily stacked and bonded, a nine-axis sensor module may be easily implemented.

Although the embodiments of the present invention have been disclosed for illustrative purposes, it will be appreciated that the present invention is not limited thereto, and those skilled in the art will appreciate that various modifications, additions and substitutions are possible, without departing from the scope and spirit of the invention.

Accordingly, any and all modifications, variations or equivalent arrangements should be considered to be within the scope of the invention, and the detailed scope of the invention will be disclosed by the accompanying claims.

What is claimed is:

1. A micro electro mechanical systems (MEMS) sensor module package comprising:
an MEMS sensor;
a base part formed so as to encapsulate the MEMS sensor with a resin;
an external terminal provided on one surface of the base part;
a through mold via (TMV) provided in the base part to electrically connect the external terminal and the MEMS sensor to each other; and
an application specific integrated circuit (ASIC) stacked on the MEMS sensor.

2. The MEMS sensor module package as set forth in claim 1, wherein the MEMS sensor is a six-axis inertial sensor.

3. The MEMS sensor module package as set forth in claim 1, further comprising an electrical shielding layer interposed between the MEMS sensor and the base part.

4. The MEMS sensor module package as set forth in claim 1, further comprising a three-axis geomagnetic sensor provided under the base part and electrically connected to the MEMS sensor.

5. The MEMS sensor module package as set forth in claim 1, wherein the base part closes one side of the MEMS sensor and opens the other side of the MEMS sensor to the outside.

6. The MEMS sensor module package as set forth in claim 1, wherein the base part closes both sides of the MEMS sensor.

7. The MEMS sensor module package as set forth in claim 1, wherein the external terminal includes a solder bump.

8. A method of manufacturing an MEMS sensor module package, comprising:
(a) bonding an MEMS sensor to an ASIC;
(b) encapsulating the MEMS sensor with a resin to form a base part;
(c) bonding a frame mold via (FMV) in which a frame and a TMV are formed integrally with each other to the base part to electrically connect the FMV to the MEMS sensor;
(d) removing or patterning the frame; and
(e) forming an external terminal on the TMV.

9. The method as set forth in claim 8, wherein the step (b) is performed by applying a liquid or powder resin.

10. The method as set forth in claim 8, further comprising, before the step (b), interposing an electrical shielding layer between the MEMS sensor and the base part.

11. The method as set forth in claim 8, further comprising (0 bonding a three-axis geomagnetic sensor to the base part to electrically connect the three-axis geomagnetic sensor to the MEMS sensor.

12. The method as set forth in claim 8, wherein the step (a) is performed by bonding the MEMS sensor to an ASIC wafer.

13. The method as set forth in claim 12, further comprising (g) sawing the ASIC wafer

14. A method of manufacturing an MEMS sensor module package, comprising:
(a) bonding an MEMS sensor to an ASIC;
(b) bonding an FMV in which a frame and a TMV are formed integrally with each other to the MEMS sensor to electrically connect the FMV to the MEMS sensor;
(c) pushing a resin between the MEMS sensor and the FMV to form a base part;
(d) removing or patterning the frame; and
(e) forming an external terminal on the TMV.

15. The method as set forth in claim 14, wherein the step (b) is performed by applying a liquid or powder resin.

16. The method as set forth in claim 14, further comprising, before the step (b), forming an electrical shielding layer under the MEMS sensor.

17. The method as set forth in claim 14, further comprising (0 bonding a three-axis geomagnetic sensor to the base part to electrically connect the three-axis geomagnetic sensor to the MEMS sensor.

18. The method as set forth in claim 14, wherein the step (a) is performed by bonding the MEMS sensor to an ASIC wafer.

19. The method as set forth in claim 18, further comprising (g) sawing the ASIC wafer.
